(19) United States
(12) Patent Application Publication
(10) Pub. No.: US 2022/0011350 A1
(43) Pub. Date: Jan. 13, 2022

(54) METHOD AND APPARATUS FOR SIMULATING AND DESIGNING STRUCTURE PARAMETERS OF AIR-CORE COIL AND ELECTRONIC DEVICE

(71) Applicant: Institute of Geology and Geophysics, Chinese Academy of Sciences, Beijing (CN)

(72) Inventors: Qingyun DI, Beijing (CN); Lili KANG, Beijing (CN); Zhongxing WANG, Beijing (CN); Zhiyao LIU, Beijing (CN); Tianxin ZHANG, Beijing (CN); Xiong YIN, Beijing (CN)

(21) Appl. No.: 17/485,106

(22) Filed: Sep. 24, 2021

Related U.S. Application Data
(63) Continuation of application No. PCT/CN2020/095300, filed on Jun. 10, 2020.

(30) Foreign Application Priority Data
Apr. 13, 2020 (CN) 202010286746.9

(51) Int. Cl. G01R 15/18; G01R 1/18

(52) U.S. Cl. CPC G01R 15/181; G01R 1/18

(57) ABSTRACT

The present invention discloses a method and apparatus for simulating and designing structural parameters of an air-core coil. The method for simulating and designing structural parameters of the air-core coil includes: building an impedance function of the air-core coil according to a structural parameter variable, the air-core coil being of a differential structure and being wound in a completely parallel winding fashion; building an index function of the air-core coil by calculating an equivalent bandwidth, sensitivity and an equivalent noise power spectrum by means of the impedance function. The method is intuitive, and makes calculation of the optimized technological and structural parameters easier and more convenient, thus reducing the amount of calculation and shortening the calculation time.

### CROSS-REFERENCE TO RELATED APPLICATIONS

This application is a bypass continuation application of PCT application no.: PCT/CN2020/095300. This application claims priorities from PCT Application No. PCT/CN2020/095300, filed Jun. 10, 2020, and from the Chinese patent application 202010286746.9 filed Apr. 13, 2020, the contents of which are incorporated herein in the entirety by reference.

### TECHNICAL FIELD

The present invention relates to the field of electromagnetic exploration technologies, in particular to a method and apparatus for simulating and designing structure parameters of an air-core coil, and an electronic device.

### BACKGROUND

The electromagnetic method is a method for realizing subsurface exploration by using electromagnetic induction principles and propagation characteristics of electromagnetic waves according to different conductivity or permeability of the earth, which is widely used in the fields of mineral resource exploration, engineering geological survey, etc. With the development of the electromagnetic theories, electromagnetic exploration technologies are being constantly updated, and borehole, ground, semi-airborne and airborne electromagnetic exploration systems are flourishing. As a medium for acquiring magnetic field, a magnetic sensor is an indispensable key part in all the electromagnetic exploration systems that require observation of magnetic fields. An air-coil sensor (ACS) is one of the frequently-used magnetic sensors, and its working principle is to convert changes of magnetic flux density passing through the coil into an induced electromotive force based on electromagnetic induction principles so as to realize measurement of the magnetic fields. The ACS is widely used in the ground, semi-airborne and airborne electromagnetic exploration systems because of its wide bandwidth, stable operation, and little impact from motion without magnetic core.

All the existing commercially-available ACSs are mainly designed to meet specific demands of specific systems, thus they are relatively short in universality and scalability. For example, in view of different exploration requirements of the ground transient electromagnetic exploration system, Geonics launched a series of sensors with different bandwidths and effective areas, including Rigid-coil and 3D-3, but this kind of ACSs is not suitable for a semi-airborne transient electromagnetic exploration system demanding higher sensitivity. In view of the requirements of an airborne electromagnetic exploration system, ACSs in VTEM and ZTEM systems launched by Geotech have relatively large effective areas, but at the same time, they are too large in size and mass, and thus are not suitable for ground or semi-airborne electromagnetic exploration systems. With the continuous development of the electromagnetic exploration technologies at present and the increasingly prominent market competition of commercially-available electromagnetic exploration systems, electromagnetic exploration instruments are becoming more and more multifunctional and efficient, and the ACSs required by the systems are also developing towards serialization and high performance. Therefore, in view of the different exploration systems and exploration requirements, it is necessary to design optimal structure and technological parameters of the ACS through simulation so as to guarantee performance indexes of the sensor.

Existing optimal design methods generally, with respect to one or more indexes including the bandwidth, effective area or noise level of the ACS, simulate and design some specific parameters such as diameter, number of turns or gain of the ACS. Asaf Grosz determined in his published paper by analytical calculation that under the conditions of a given frequency, coil volume, diameter ratio, magnetic core, dielectric constant of the skeleton and noise of the amplifier, an induction magnetometer (IM) with a magnetic core includes the following optimal design parameters: diameter and turns per coil. Yan Bin, et al. optimized the design of the diameter and the coil turns of the IM under the conditions of a limited volume, limited mass and given magnetic core in the case that the other conditions are similar. Shi Hongyu described a selection principle of materials for the magnetic core in the IM design, and provided an optimal design method for diameter and number of turns of an air-core coil in the IM according to mass and volume limits under the condition that the magnetic core is given. Chen Shudong, Chen Chen, Liu Fei, et al. simulated and designed applicable ACSs for different airborne transient electromagnetic exploration systems and requirements. In the above optimized design methods, the problem of parameter design for a coil sensor is coincidentally transformed into the problem of solving an optimal solution of an equation set with constraints analytically by introducing the Lagrange operator and the least square fitting algorithm etc., i.e.,

First of all, due to inadequate strategies including an indefinite relationship among index requirements, technological and/or structure parameters, and imperfect optimizable parameters, the existing ACS simulating and designing method fails to meet the demand required by exploration systems for serialized and high-performance developments. Secondly, all the existing ACS parameter optimal designing methods acquire definite ACS optimal design parameters via the analytical solution by solving an optimal solution of an equation set using a Lagrange operator and least square fitting algorithm. This analytical solution of the optimal solution has a complicated algorithm and takes a long time for calculation, and its calculation accuracy is easily affected by adjustable parameters in the equation set. Especially, when the number of constraints or parameters to be optimized is increased, the complexity of this algorithm will obviously increase and the effectiveness will obviously decrease.

### SUMMARY

### (I) Objective of the Invention

An objective of the present invention is to provide a method and apparatus for simulating and designing structure parameters of an air-core coil, and an electronic device, to solve the problems in the prior art that calculation of structure parameters of an air-core coil is complicated and time-consuming.

### (II) Technical Solution

To solve the above-mentioned problems, in a first aspect of the present invention, a method for simulating and designing structure parameters of an air-core coil is provided. The method includes: building an impedance function of the air-core coil according to structure parameters, regarding the air-core coil as a differential structure with completely parallel wires; building a target function of the air-core coil by calculating an equivalent bandwidth, sensitivity and equivalent noise power spectrum density by means of the impedance function; building a qualified function with reference to the target function and structure parameters limit by using a mass and/or volume limit; and acquiring structure parameters of the air-core coil by calculating an optimal solution of the qualified function.

Further, said building the impedance function of the air-core coil according to the structure parameters include: calculating an internal impedance function of the air-core coil which includes an equivalent inductance function, a stray capacitance function and an equivalent internal resistance function; setting a damping coefficient and calculating a matching resistance function of the air-core coil, wherein the equivalent inductance function is

$$L = \frac{{μ}_{0} {DN}^{2}}{8} [ ln ( \frac{8 {DN}_{s}}{l} ) - 0.5 ] ;$$

in which, D is an average diameter of the air-core coil, D=(D₀+(d_{c}+d)N_{c}); D₀ is an internal diameter of a skeleton of the air-core coil; d is an external diameter of a coil wire; d_{c} is an inter-layer spacing between coil wires; and N_{c} is the number of wire layers of the air-core coil;

the stray capacitance function is

C=Cₗ+Cₐ+C_{g};

in which,

$${C}_{l} = \frac{{ɛ}_{0} {ɛ}_{l} \sqrt{1 + {( π D \text{/} {d}_{w} )}^{2}}}{36 In ( {d}_{w} \text{/} d )}$$

is an inter-turn capacitance function;

$${C}_{a} = \frac{{ɛ}_{0} {ɛ}_{a} Dl ( {N}_{c} - 1 )}{{N}_{s} {d}_{w} {N}_{c}^{2}}$$

is an inter-layer capacitance function;

$${C}_{g} = \frac{4 {ɛ}_{0} {ɛ}_{g} D ( {d}_{c} + d ) {N}_{c} ( {N}_{s} - 1 )}{3 {eN}_{s}^{2}}$$

is an inter-segment capacitance function, wherein ε₀, εₗ, εₐ and ε_{g} are a dielectric constant of vacuum, a dielectric constant of an inter-turn medium, a dielectric constant of an inter-layer medium and a dielectric constant of an inter-segment medium, respectively; Nₛ is the number of segments of the air-core coil; e is an inter-segment spacing of the air-core coil; d_{w} is a center distance of a wire of the air-core coil; and l is a slot width of the single-segment air-core coil;

the equivalent internal resistance function is

$$r = \frac{4 ρ ( {D}_{0} + ( {d}_{c} + d ) {N}_{c} )}{{d}^{2}} ;$$

in which, ρ is specific resistance of a wire core;

the damping coefficient and the internal impedance function as well as the matching resistance function of the air-core coil meet the following matching function:

$$ζ = \frac{RrC + L}{2 \sqrt{LCR ( R + r )}} ;$$

the damping coefficient can be set to a specific value greater than 1, equal to 1 or less than 1; the air-core coil is in an over-damped state when the damping coefficient is greater than 1; the air-core coil is in a critical damped state when the damping coefficient is equal to 1; and the air-core coil is in an under-damped state when the damping coefficient is less than 1; and calculating the matching resistance function based on the internal impedance function and the set value of the damping coefficient:

$$R = \frac{( 4 {ζ}^{2} - 2 ) LCr - \sqrt{{[ ( 4 {ζ}^{2} - 2 ) LCr ]}^{2} - 4 ( {r}^{2} {C}^{2} - 4 ζ LC ) {L}^{2}}}{2 ( {r}^{2} {C}^{2} - 4 ζ LC )} .$$

Further, said building the target function of the air-core coil by calculating the equivalent bandwidth, the sensitivity and the equivalent noise power spectrum by means of the impedance function specifically includes: building an equivalent bandwidth relation function, a sensitivity relation function and an equivalent noise power spectral density relation function by calculating the equivalent bandwidth, the sensitivity and the equivalent noise power spectrum by means of the impedance function.

Further, the equivalent bandwidth function is

$${B}_{w} = \frac{1}{2 π \sqrt{LC}} \sqrt{1 + \frac{r}{R}} \sqrt{1 - 2 {ζ}^{2} + \sqrt{4 {ζ}^{4} - 4 {ζ}^{2} + 2}} ;$$

in which, B_{w} is an equivalent bandwidth function; L is an equivalent inductance function; C is a stray capacitance function; r is an equivalent internal resistance function; ζ is a damping coefficient; and R is a matching resistance function.

Further, the sensitivity function is

S_{c}(ω)=2πƒNS|H(ω)|;

in which, H(ω) is a transfer function of an air-core coil sensor, which is acquired by the product of a transfer function H_{c}(ω) of the single-segment air-core coil and a transfer function H_{A} (ω) of a pre-amplifier, i.e., H(ω)=2H_{c}(ω)H_{A} (ω);

the transfer function of the single-segment air-core coil is

$${H}_{c} ( ω ) = \frac{1}{LC \sqrt{{ω}_{p}^{4} + 8 {π}^{2} {f}^{2} ( 2 {π}^{2} {f}^{2} + {ω}_{p}^{2} ( 2 {ζ}^{2} - 1 )}} ;$$

in which,

$${ω}_{p} = \sqrt{\frac{1}{LC} ( \frac{r}{R} + 1 )}$$

is a resonant angular frequency function of the air-core coil: L is an equivalent inductance function; C is a stray capacitance function; r is an equivalent internal resistance function; ζ is a damping coefficient: R is a matching resistance function, and H_{A}(ω) is acquired according to an equivalent circuit model of an actual pre-amplifier.

Further, the equivalent noise power spectral density function is

$${B}_{n} ( ω ) = \frac{{E}_{n} ( ω )}{{S}_{c} ( ω )} ;$$

in which, S_{c}(ω) is a sensitivity function of the air-core coil and Eₙ(ω)=\sqrt{Eₙᵣ²+Eₙᵢ²+Eₙᵥ²} is an equivalent input voltage noise power spectral density function of the air-core coil sensor; and in the equivalent input voltage noise power spectral density function, Eₙᵣ, Eₙᵢ and Eₙᵥ are equivalent input resistance thermal noise, equivalent input offset voltage noise and equivalent input offset current noise of the air-core coil sensor, respectively, which are acquired based on the impedance function of the air-core coil and the equivalent circuit model of the actual pre-amplifier.

Further, said acquiring the structure parameters of the air-core coil by calculating the optimal solution of the qualified function specifically includes: acquiring the structure parameters by calculating the optimal solution of the qualified function via a numerical method.

Further, said acquiring the structure parameters of the air-core coil by calculating the optimal solution of the qualified function includes: calculating and drawing a corresponding qualified function curve based on a value range of the structure parameters, the target function and a mass and/or volume limit; and calculating a solution corresponding to the target function by using particularities of a projection, an isoline, an extreme point, an intersection point and a tangent point of the qualified function curve so as to obtain the structure parameters of the air-core coil.

According to another aspect of the present invention, an apparatus for simulating and designing structure parameters of an air-core coil is provided. The apparatus includes: an impedance function building module configured to build an impedance function of the air-core coil according to structure parameters, the air-core coil being of a differential structure and being wound in a completely parallel winding fashion; a target function building module configured to build a target function of the air-core coil by calculating an equivalent bandwidth, sensitivity and an equivalent noise power spectrum by means of the impedance function; a qualified function building module configured to build a qualified function with reference to the target function and structure parameters limit by using a mass and/or volume limit; and a structure parameter calculating module configured to acquire the structure parameters of the air-core coil by calculating an optimal solution of the qualified function.

Further, the impedance function building module includes: an internal impedance calculating unit configured to calculate an equivalent inductance function, a stray capacitance function and an equivalent internal resistance function of the air-core coil; and a matching impedance calculating unit configured to set a damping coefficient and to calculate a matching resistance function of the air-core coil, wherein the equivalent inductance function is

$$L = \frac{{μ}_{0} {DN}^{2}}{8} [ ln ( \frac{8 {DN}_{s}}{l} ) - 0.5 ] ;$$

in which, D is an average diameter of the air-core coil, D=(D₀+(d_{c}+d)N_{c}); D₀ is an internal diameter of a skeleton of the air-core coil; d is an external diameter of a coil wire; d_{c} is an inter-layer spacing between coil wires; and N_{c} is the number of wire layers of the air-core coil;

the stray capacitance function is

C=Cₗ+Cₐ+C_{g};

in which,

$${C}_{l} = \frac{{ɛ}_{0} {ɛ}_{l} \sqrt{1 + {( π D \text{/} {d}_{w} )}^{2}}}{36 In ( {d}_{w} \text{/} d )}$$

is an inter-turn capacitance function;

$${C}_{a} = \frac{{ɛ}_{0} {ɛ}_{a} Dl ( {N}_{c} - 1 )}{{N}_{s} {d}_{w} {N}_{c}^{2}}$$

is an inter-layer capacitance function;

$${C}_{g} = \frac{4 {ɛ}_{0} {ɛ}_{g} D ( {d}_{c} + d ) {N}_{c} ( {N}_{s} - 1 )}{3 {eN}_{s}^{2}}$$

is an inter-segment capacitance function, wherein ε₀, εₗ, εₐ and ε_{g} are a dielectric constant of vacuum, a dielectric constant of an inter-turn medium, a dielectric constant of an inter-layer medium and a dielectric constant of an inter-segment medium, respectively; Nₛ is the number of segments of the air-core coil; e is an inter-segment spacing of the air-core coil; d_{w} is a center distance of a wire of the air-core coil; and l is a slot width of the single-segment air-core coil;

the equivalent internal resistance function is

$$r = \frac{4 ρ ( {D}_{0} + ( {d}_{c} + d ) {N}_{c} )}{{d}^{2}} ;$$

in which, ρ is specific resistance of a wire core;

the damping coefficient and the equivalent inductance function, the stray capacitance function, the equivalent internal resistance function and the matching resistance function of the air-core coil meet the following matching function:

$$ζ = \frac{RrC + L}{2 \sqrt{LCR ( R + r )}} ;$$

the damping coefficient can be set to a specific value greater than 1, equal to 1 or less than 1; the air-core coil is in an over-damped state when the damping coefficient is greater than 1; the air-core coil is in a critical damped state when the damping coefficient is equal to 1; the air-core coil is in an under-damped state when the damping coefficient is less than 1; and the matching resistance function is calculated based on the impedance function and the set value of the damping coefficient:

$$R = \frac{( 4 {ζ}^{2} - 2 ) LCr - \sqrt{{[ ( 4 {ζ}^{2} - 2 ) LCr ]}^{2} - 4 ( {r}^{2} {C}^{2} - 4 ζ LC ) {L}^{2}}}{2 ( {r}^{2} {C}^{2} - 4 ζ LC )} .$$

Further, the target function building module is specifically configured to build an equivalent bandwidth relation function, a sensitivity relation function and an equivalent noise power spectral density relation function by calculating the equivalent bandwidth, the sensitivity and the equivalent noise power spectrum of the air-core coil by means of the impedance function.

Further, the equivalent bandwidth function is

$${B}_{w} = \frac{1}{2 π \sqrt{LC}} \sqrt{1 + \frac{r}{R}} \sqrt{1 - 2 {ζ}^{2} + \sqrt{4 {ζ}^{4} - 4 {ζ}^{2} + 2}} ;$$

in which, B_{w} is an equivalent bandwidth function; L is an equivalent inductance function; C is a stray capacitance function; r is an equivalent internal resistance function; ζ is a damping coefficient; and R is a matching resistance function.

Further, the sensitivity function is

S_{c}(ω)=2πƒNS|H(ω)|;

in which, H(ω) is a transfer function of an air-core coil sensor, which is acquired by the product of a transfer function H(ω) of the single-segment air-core coil and a transfer function H_{A} (ω) of a pre-amplifier, i.e., H(ω)=2H_{c}(ω)H_{A} (ω); the transfer function of the single-segment air-core coil is

$${H}_{c} ( ω ) = \frac{1}{LC \sqrt{{ω}_{p}^{4} + 8 {π}^{2} {f}^{2} ( 2 {π}^{2} {f}^{2} + {ω}_{p}^{2} ( 2 {ζ}^{2} - 1 )}} ;$$

in which,

$${ω}_{p} = \sqrt{\frac{1}{LC} ( \frac{r}{R} + 1 )}$$

is a resonant angular frequency function of the single-segment air-core coil; L is an equivalent inductance function: C is a stray capacitance function: r is an equivalent internal resistance function; ζ is a damping coefficient; R is a matching resistance function; and H_{A}(ω) is acquired according to an equivalent circuit model of an actual pre-amplifier.

Further, the equivalent noise power spectral density function is

$${B}_{n} ( ω ) = \frac{{E}_{n} ( ω )}{{S}_{c} ( ω )} ;$$

in which, S_{c}(ω) is the sensitivity function of the air-core coil and Eₙ(ω)=\sqrt{Eₙᵣ²+Eₙᵢ²+Eₙᵥ²} is an equivalent input voltage noise power spectral density function of the air-core coil sensor; and in the equivalent input voltage noise power spectral density function, Eₙᵣ, Eₙᵢ and Eₙᵥ are equivalent input resistance thermal noise, equivalent input offset voltage noise and equivalent input offset current noise of the air-core coil sensor respectively, which are acquired by calculating based on the impedance function of the air-core coil and the equivalent circuit model of the actual pre-amplifier.

Further, the structure parameter calculating module is specifically configured to acquire the structure parameters by calculating the optimal solution of the qualified function via a numerical method.

Further, the structure parameter calculating module includes: a qualified function curve drawing module configured to calculate and draw a corresponding qualified function curve based on a value range of the structure parameters, the target function and a mass and/or volume limit; and a structure parameter calculating module configured to calculate a solution corresponding to the target function by using particularities of a projection, an isoline, an extreme point, an intersection point and a tangent point of the qualified function curve so as to acquire the structure parameters of the air-core coil.

According to yet another aspect of the present invention, a storage medium storing a computer program is provided. The computer program, when executed by a processor, causes the processor to implement the steps of the method according to any one of the above-mentioned technical solutions.

According to still another aspect of the present invention, an electronic device is provided. The electronic device includes a memory, a display, a processor and a computer program stored on the memory and operable on the processor. The computer program, when executed by the processor, causes the processor to implement the steps of the method according to any one of the above-mentioned technical solutions.

### (III) Beneficial Effects

The present invention has the following beneficial technical effects.

The method provided by the present invention is intuitive, and makes calculation of the optimized technological and structure parameters easier and more convenient, thus reducing the amount of calculation and shortening the calculation time.

### BRIEF DESCRIPTION OF THE DRAWINGS

FIG. 1 is a flowchart of a method for simulating and designing structure parameters of an air-core coil according to a first embodiment of the present invention;

FIG. 2 is a schematic structure diagram of an air-core coil sensor according to an optional embodiment of the present invention;

FIG. 3 is a schematic diagram of an air-core coil which is of a differential structure and is wound in a completely parallel winding fashion according to an optional embodiment of the present invention;

FIG. 4 is a circuit diagram of impedance matching between two differential output ends of an air-core coil by parallel connection of a matching resistor according to an optional embodiment of the present invention;

FIG. 5 is a flowchart of a method for designing technological and structure parameters of an air-core coil according to an optional embodiment of the present invention;

FIG. 6 is a diagram of a pre-amplifying circuit for an air-core coil sensor according to a specific embodiment of the present invention;

FIG. 7 is a diagram of an effective area and a bandwidth of an air-core coil sensor according to a specific embodiment of the present invention, in which (a) indicates an effective area; (b) indicates a bandwidth when a wire has the diameter of 0.2 mm; (c) indicates a bandwidth when a wire has the diameter of 0.6 mm; and (d) indicates a bandwidth when a wire has the diameter of 0.8 mm;

FIG. 8 is a designed curve graph of the number of turns and radius of an air-core coil according to a specific embodiment of the present invention, in which (a) indicates an optimized design curve of turns per coil; and (b) indicates a designed curve of a coil diameter; and

FIG. 9 is a diagram of a noise level of an air-core coil sensor according to a specific embodiment of the present invention.

### DETAILED DESCRIPTION

To make the objectives, technical solutions and advantages of the present invention clearer, the present invention will be described in detail below with reference to specific embodiments and the accompanying drawings. It should be understood that these descriptions are merely exemplary, and are not intended to limit the scope of the present invention. In addition, in the following illustration, descriptions of well-known structures and technologies are omitted to avoid unnecessarily obscuring the concept of the present invention.

It is obvious that the described embodiments are part rather than all of the embodiments of the present invention. All other embodiments obtained by those of ordinary skill in the art based on the embodiments of the present invention without creative work shall fall within the scope of protection of the present invention.

Moreover, the technical features involved in the different embodiments of the present invention described below can be combined together as long as they are not in conflict with one another.

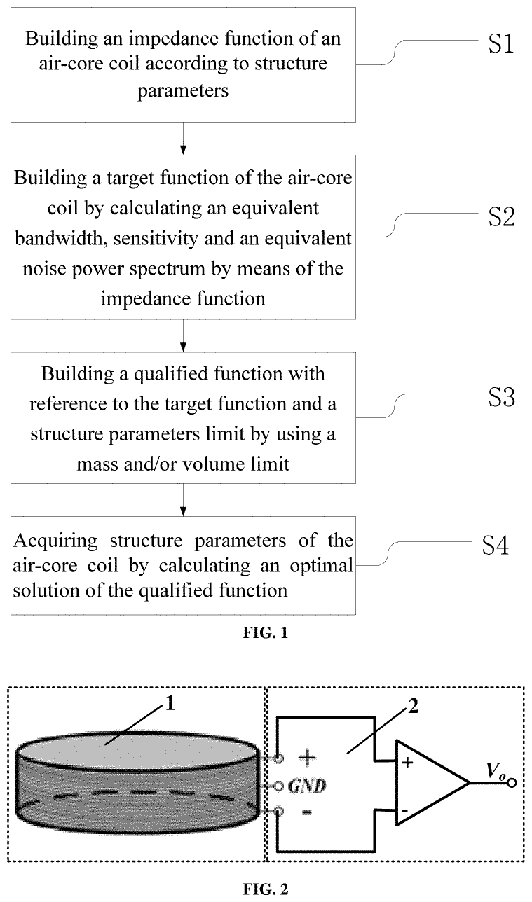

As shown in FIG. 1, in a first aspect of the present invention, a method for simulating and designing structure parameters of an air-core coil is provided. The method includes:

building an impedance function of an air-core coil according to structure parameters, the air-core coil being of a differential structure and being wound in a completely parallel winding fashion;

building a target function of the air-core coil by calculating an equivalent bandwidth, sensitivity and an equivalent noise power spectrum by means of the impedance function;

building a qualified function with reference to the target function and structure parameters limit by using a mass and/or volume limit; and

acquiring structure parameters of the air-core coil by calculating an optimal solution of the qualified function.

Optionally, said building the impedance function of the air-core coil according to the structure parameters includes:

calculating an internal impedance function of the air-core coil, the internal impedance function including an equivalent inductance function, a stray capacitance function and an equivalent internal resistance function;

setting a damping coefficient and calculating a matching resistance function of the air-core coil, wherein

the equivalent inductance function is

$$L = \frac{{μ}_{0} {DN}^{2}}{8} [ ln ( \frac{8 {DN}_{s}}{l} ) - 0.5 ] ;$$

in which, D is an average diameter of the air-core coil, D=(D₀+(d_{c}+d)N_{c}); D₀ is an internal diameter of a skeleton of the air-core coil; d is an external diameter of a coil wire; d_{c} is an inter-layer spacing between coil wires; and N_{c} is the number of wire layers of the air-core coil;

the stray capacitance function is

C=Cₗ+Cₐ+C_{g};

in which,

$${C}_{l} = \frac{{ɛ}_{0} {ɛ}_{l} \sqrt{1 + {( π D \text{/} {d}_{w} )}^{2}}}{36 In ( {d}_{w} \text{/} d )}$$

is an inter-turn capacitance function;

$${C}_{a} = \frac{{ɛ}_{0} {ɛ}_{a} Dl ( {N}_{c} - 1 )}{{N}_{s} {d}_{w} {N}_{c}^{2}}$$

is an inter-layer capacitance function;

$${C}_{g} = \frac{4 {ɛ}_{0} {ɛ}_{g} D ( {d}_{c} + d ) {N}_{c} ( {N}_{s} - 1 )}{3 {eN}_{s}^{2}}$$

is an inter-segment capacitance function, wherein ε₀, εₗ, εₐ and ε_{g} are a dielectric constant of vacuum, a dielectric constant of an inter-turn medium, a dielectric constant of an inter-layer medium and a dielectric constant of an inter-segment medium, respectively; Nₛ is the number of segments of the air-core coil; e is an inter-segment spacing of the air-core coil; d_{w} is a center distance of a wire of the air-core coil; and l is a slot width of the single-segment air-core coil;

the equivalent internal resistance function is

$$r = \frac{4 ρ ( {D}_{0} + ( {d}_{c} + d ) {N}_{c} )}{{d}^{2}} ;$$

in which, ρ is specific resistance of a wire core;

the damping coefficient and the internal impedance function as well as the matching resistance function of the air-core coil meet the following matching function:

$$ζ = \frac{RrC + L}{2 \sqrt{LCR ( R + r )}} ;$$

the damping coefficient can be set to a specific value greater than 1, equal to 1 or less than 1; the air-core coil is in an over-damped state when the damping coefficient is greater than 1; the air-core coil is in a critical damped state when the damping coefficient is equal to 1; and the air-core coil is in an under-damped state when the damping coefficient is less than 1; and

calculating the matching resistance function based on the internal impedance function and the set value of the damping coefficient:

$$R = \frac{( 4 {ζ}^{2} - 2 ) LCr - \sqrt{{[ ( 4 {ζ}^{2} - 2 ) LCr ]}^{2} - 4 ( {r}^{2} {C}^{2} - 4 ζ LC ) {L}^{2}}}{2 ( {r}^{2} {C}^{2} - 4 ζ LC )} .$$

Optionally, said building the target function of the air-core coil by calculating the equivalent bandwidth, the sensitivity and the equivalent noise power spectrum by means of the impedance function specifically includes:

building an equivalent bandwidth relation function, a sensitivity relation function and an equivalent noise power spectral density relation function by calculating the equivalent bandwidth, the sensitivity and the equivalent noise power spectrum of the air-core coil by means of the impedance function.

Optionally, the equivalent bandwidth function is

$${B}_{w} = \frac{1}{2 π \sqrt{LC}} \sqrt{1 + \frac{r}{R}} \sqrt{1 - 2 {ζ}^{2} + \sqrt{4 {ζ}^{4} - 4 {ζ}^{2} + 2}} ;$$

in which, B_{w} is an equivalent bandwidth function; L is an equivalent inductance function; C is a stray capacitance function; r is an equivalent internal resistance function; ζ is a damping coefficient; and R is a matching resistance function.

Optionally, the sensitivity function is

S_{c}(ω)=2πƒNS|H(ω)|;

in which, H(ω) is a transfer function of an air-core coil sensor, which is acquired by the product of a transfer function H_{c}(ω) of the single-segment air-core coil and a transfer function H_{A} (ω) of a pre-amplifier, i.e., H(ω)=2H_{c}(ω)H_{A}(ω);

the transfer function of the single-segment air-core coil is

$${H}_{c} ( ω ) = \frac{1}{LC \sqrt{{ω}_{p}^{4} + 8 {π}^{2} {f}^{2} ( 2 {π}^{2} {f}^{2} + {ω}_{p}^{2} ( 2 {ζ}^{2} - 1 )}} ;$$

in which,

$${ω}_{p} = \sqrt{\frac{1}{LC} ( \frac{r}{R} + 1 )}$$

is a resonant angular frequency function of the single-segment air-core coil; L is an equivalent inductance function; C is a stray capacitance function; r is an equivalent internal resistance function; ζ is a damping coefficient, and R is a matching resistance function; and

H_{A}(ω) is acquired according to an equivalent circuit model of an actual pre-amplifier.

Optionally, the equivalent noise power spectral density function is

$${B}_{n} ( ω ) = \frac{{E}_{n} ( ω )}{{S}_{c} ( ω )} ;$$

in which, S_{c}(ω) is a sensitivity function of the air-core coil and Eₙ(ω)=\sqrt{Eₙᵣ²+Eₙᵢ²+Eₙᵥ²} is an equivalent input voltage noise power spectral density function of the air-core coil sensor; and

in the equivalent input voltage noise power spectral density function, Eₙᵥ, Eₙᵢ and Eₙᵥ are equivalent input resistance thermal noise, equivalent input offset voltage noise and equivalent input offset current noise of the air-core coil sensor respectively, which are acquired by calculating based on the impedance function of the air-core coil and the equivalent circuit model of the actual pre-amplifier.

Optionally, said acquiring the structure parameters of the air-core coil by calculating the optimal solution of the qualified function specifically includes:

Acquiring the structure parameters by calculating the optimal solution of the qualified function via a numerical method.

Optionally, said acquiring the structure parameters of the air-core coil by calculating the optimal solution of the qualified function includes:

calculating and drawing a corresponding qualified function curve based on a value range of the structure parameters, the target function and a mass and/or volume limit; and

calculating a solution corresponding to the target function by using particularities of a projection, an isoline, an extreme point, an intersection point and a tangent point of the qualified function curve so as to acquire the structure parameters of the air-core coil.

According to another aspect of the present invention, an apparatus for simulating and designing structure parameters of an air-core coil is provided. The apparatus includes:

an impedance function building module configured to build an impedance function of the air-core coil according to structure parameters, the air-core coil being of a differential structure and being wound in a completely parallel winding fashion;

a target function building module configured to build a target function of the air-core coil by calculating an equivalent bandwidth, sensitivity and an equivalent noise power spectrum by means of the impedance function;

a qualified function building module configured to build a qualified function with reference to the target function and structure parameters limit by using a mass and/or volume limit; and

a structure parameter calculating module configured to acquire the structure parameters of the air-core coil by calculating an optimal solution of the qualified function.

Optionally, the impedance function building module includes:

an internal impedance calculating unit configured to calculate an equivalent inductance function, a stray capacitance function and an equivalent internal resistance function of the air-core coil; and

a matching impedance calculating unit configured to set a damping coefficient and to calculate a matching resistance function of the air-core coil, wherein

the equivalent inductance function is

$$L = \frac{{μ}_{0} {DN}^{2}}{8} [ ln ( \frac{8 {DN}_{s}}{l} ) - 0.5 ] ;$$

in which, D is an average diameter of the air-core coil, D=(D₀+(d_{c}+d)N_{c}); D₀ is an internal diameter of a skeleton of the air-core coil; d is an external diameter of a coil wire; d_{c} is an inter-layer spacing between coil wires; and N_{c} is the number of wire layers of the air-core coil;

the stray capacitance function is

C=Cₗ+Cₐ+C_{g};

in which,

$${C}_{l} = \frac{{ɛ}_{0} {ɛ}_{l} \sqrt{1 + {( π D \text{/} {d}_{w} )}^{2}}}{36 In ( {d}_{w} \text{/} d )}$$

is an inter-turn capacitance function;

$${C}_{a} = \frac{{ɛ}_{0} {ɛ}_{a} Dl ( {N}_{c} - 1 )}{{N}_{s} {d}_{w} {N}_{c}^{2}}$$

is an inter-layer capacitance function;

$${C}_{g} = \frac{4 {ɛ}_{0} {ɛ}_{g} D ( {d}_{c} + d ) {N}_{c} ( {N}_{s} - 1 )}{3 {eN}_{s}^{2}}$$

is an inter-segment capacitance function, wherein ε₀, εₗ, εₐ and ε_{g} are a dielectric constant of vacuum, a dielectric constant of an inter-turn medium, a dielectric constant of an inter-layer medium and a dielectric constant of an inter-segment medium, respectively; Nₛ is the number of segments of the air-core coil; e is an inter-segment spacing of the air-core coil; d_{w} is a center distance of a wire of the air-core coil; and l is a slot width of the single-segment air-core coil;

the equivalent internal resistance function is

$$r = \frac{4 ρ ( {D}_{0} + ( {d}_{c} + d ) {N}_{c} )}{{d}^{2}} ;$$

in which, ρ is specific resistance of a wire core;

the damping coefficient and the equivalent inductance function, the stray capacitance function, the equivalent internal resistance function and the matching resistance function of the air-core coil meet the following matching function:

$$ζ = \frac{RrC + L}{2 \sqrt{LCR ( R + r )}} ;$$

the damping coefficient can be set to a specific value greater than 1, equal to 1 or less than 1; the air-core coil is in an over-damped state when the damping coefficient is greater than 1; the air-core coil is in a critical damped state when the damping coefficient is equal to 1; the air-core coil is in an under-damped state when the damping coefficient is less than 1; and

the matching resistance function is calculated based on the impedance function and the set value of the damping coefficient:

$$R = \frac{( 4 {ζ}^{2} - 2 ) LCr - \sqrt{{[ ( 4 {ζ}^{2} - 2 ) LCr ]}^{2} - 4 ( {r}^{2} {C}^{2} - 4 ζ LC ) {L}^{2}}}{2 ( {r}^{2} {C}^{2} - 4 ζ LC )} .$$

Optionally, the target function building module is specifically configured to build an equivalent bandwidth relation function, a sensitivity relation function and an equivalent noise power spectral density relation function by calculating the equivalent bandwidth, the sensitivity and the equivalent noise power spectrum of the air-core coil by means of the impedance function.

Optionally, the equivalent bandwidth function is

$${B}_{w} = \frac{1}{2 π \sqrt{LC}} \sqrt{1 + \frac{r}{R}} \sqrt{1 - 2 {ζ}^{2} + \sqrt{4 {ζ}^{4} - 4 {ζ}^{2} + 2}} ;$$

in which, B_{w} is an equivalent bandwidth function; L is an equivalent inductance function; C is a stray capacitance function; r is an equivalent internal resistance function; ζ is a damping coefficient; and R is a matching resistance function.

Optionally, the sensitivity function is

S_{c}(ω)=2πƒNS|H(ω)|;

in which, H(ω) is a transfer function of an air-core coil sensor, which is acquired by the product of a transfer function H_{c}(ω) of the single-segment air-core coil and a transfer function H_{A}(ω) of a pre-amplifier, i.e., H(ω)=2H_{c}(ω)H_{A} (ω);

the transfer function of the single-segment air-core coil is

$${H}_{c} ( ω ) = \frac{1}{LC \sqrt{{ω}_{p}^{4} + 8 {π}^{2} {f}^{2} ( 2 {π}^{2} {f}^{2} + {ω}_{p}^{2} ( 2 {ζ}^{2} - 1 )}} ;$$

in which,

$${ω}_{p} = \sqrt{\frac{1}{LC} ( \frac{r}{R} + 1 )}$$

is a resonant angular frequency function of the air-core coil; L is an equivalent inductance function; C is a stray capacitance function; r is an equivalent internal resistance function; ζ is a damping coefficient; R is a matching resistance function; and

H_{A}(ω) is acquired according to an equivalent circuit model of an actual pre-amplifier.

Optionally, the equivalent noise power spectral density function is

$${B}_{n} ( ω ) = \frac{{E}_{n} ( ω )}{{S}_{c} ( ω )} ;$$

in which, S_{c}(ω) is a sensitivity function of the air-core coil and Eₙ(ω)=\sqrt{Eₙᵣ²+Eₙᵢ²+Eₙᵥ²} is an equivalent input voltage noise power spectral density function of the air-core coil sensor; and

in the equivalent input voltage noise power spectral density function, Eₙᵣ, Eₙᵢ and Eₙᵥ are equivalent input resistance thermal noise, equivalent input offset voltage noise and equivalent input offset current noise of the air-core coil sensor respectively, which are acquired by calculating based on the impedance function of the air-core coil and the equivalent circuit model of the actual pre-amplifier.

Optionally, the structure parameter calculating module is specifically configured to acquire the structure parameters by calculating the optimal solution of the qualified function via a numerical method.

Optionally, the structure parameter calculating module includes:

a qualified function curve drawing module configured to calculate and draw a corresponding qualified function curve based on a value range of the structure parameters, the target function and a mass and/or volume limit; and

a structure parameter calculating module configured to calculate a solution corresponding to the target function by using particularities of a projection, an isoline, an extreme point, an intersection point and a tangent point of the qualified function curve so as to acquire the structure parameters of the air-core coil.

According to yet another aspect of the present invention, a storage medium storing a computer program is provided. The computer program, when executed by a processor, causes the processor to implement the steps of the method according to any one of the above-mentioned technical solutions.

According to still another embodiment of the present invention, an electronic device is provided. The electronic device includes a memory, a display, a processor and a computer program stored in the memory and operable on the processor. The computer program, when executed by the processor, causes the processor to implement the steps of the method according to any one of the above-mentioned technical solutions.

As shown in FIG. 2, the air-core coil sensor consists of two parts, namely an air-core coil and a pre-amplifying circuit.

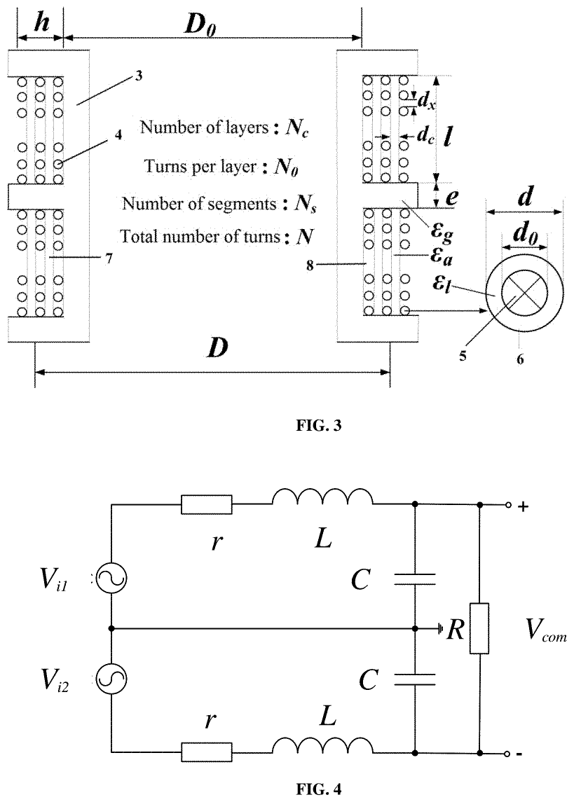

As shown in FIG. 3, the air-core coil in the air-core coil sensor is of a differential structure and is wound in a completely parallel winding fashion.

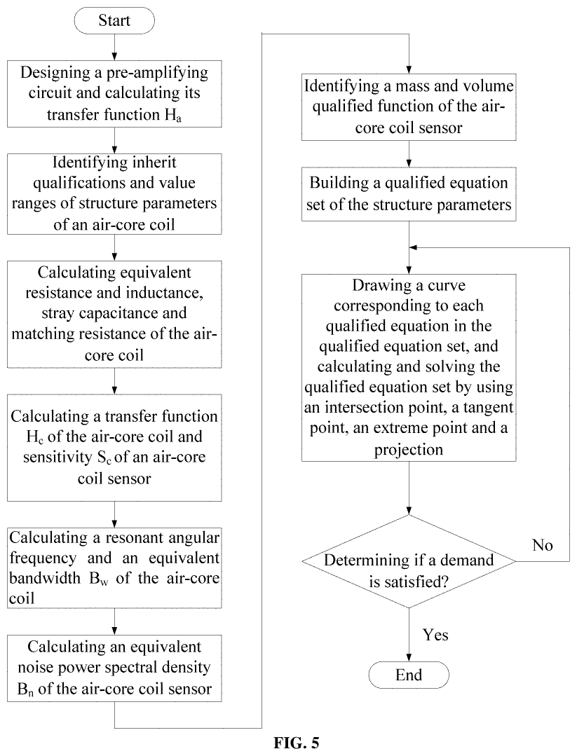

As shown in FIG. 4, impedance matching between two differential output ends of the air-core coil is realized by parallel connection of a matching resistor.

As shown in FIG. 5, a method for simulating and designing structure parameters of an air-core coil is provided according to an optional embodiment of the present invention. The method includes:

step a: designing a pre-amplifying circuit of an air-core coil sensor and providing a circuit model and a transfer function H_{A}(W) of the pre-amplifying circuit;

step b: identifying inherit qualifications and a value range of structure and technological parameters of the air-core coil sensor;

step c: calculating equivalent internal resistance r, equivalent inductance L, and stray capacitance C of a coil according to the technological and structure parameters of the coil, providing a damping coefficient and calculating matching resistance R;

step d: calculating a transfer function H_{c} and equivalent magnetic field sensitivity S_{c} of the air-core coil;

step e: calculating a resonant angular frequency ωₚ and an equivalent bandwidth B_{w} of the air-core coil based on the transfer function in the step c;

step f: acquiring an equivalent input magnetic field noise power spectral density Bₙ of the air-core coil sensor by calculating equivalent internal resistance thermal noise Nᵣ corresponding to all resistors in the air-core coil sensor, and equivalent voltage noise Nᵥ and equivalent current noise Nₐ at input terminals of all amplifiers;

step h: identifying function qualified relations Fₘ and Fᵥ between mass M and volume V qualifications of the air-core coil and the technological and structure parameters of the air-core coil sensor;

step i: building a qualified equation set of the technological and structure parameters of the air-core coil sensor in view of the qualified function of the technological and structure parameters in step h according to design requirements on the sensitivity, bandwidth and noise of the air-core coil sensor; and

step j: acquiring a design combination of the technological and structure parameters of the air-core coil by solving a solution of the qualified equation set of the technological and structure parameters of the air-core coil sensor by means of a numerical method.

In step c, a calculation formula of the equivalent internal resistance is

$$r = \frac{4 ρ ( {D}_{0} + ( {d}_{c} + d ) {N}_{c} )}{{d}^{2}} ,$$

and a calculation formula of the equivalent inductance is

$$L = \frac{{μ}_{0} {DN}^{2}}{8} [ ln ( \frac{8 {DN}_{s} )}{l} ) - 0.5 ] ,$$

in which D is an average diameter of the air-core coil, D=(D₀+(d_{c}+d)N_{c}); D₀ is an internal diameter of a skeleton of the air-core coil; d is an external diameter of a coil wire; d_{c} is an inter-layer spacing between coil wires; N_{c} is the number of wire layers of the air-core coil; a calculation formula of the stray capacitance is C=Cₗ+Cₐ+C_{g}, in which,

$${C}_{l} = \frac{{ɛ}_{0} {ɛ}_{l} \sqrt{1 + {( π D \text{/} {d}_{w} )}^{2}}}{36 In ( {d}_{w} \text{/} d )} , {C}_{a} = \frac{{ɛ}_{0} {ɛ}_{a} Dl ( {N}_{c} - 1 )}{{N}_{s} {d}_{w} {N}_{c}^{2}} and {C}_{g} = \frac{4 {ɛ}_{0} {ɛ}_{g} D ( {d}_{c} + N ) {N}_{c} ( {N}_{s} - 1 )}{3 {eN}_{s}^{2}} ,$$

wherein ε₀, εₗ, εₐ and ε_{g} are a dielectric constant of vacuum, a dielectric constant of an inter-turn medium, a dielectric constant of an inter-layer medium and a dielectric constant of an inter-segment medium, respectively; Nₛ is the number of segments of the air-core coil; e is an inter-segment spacing of the air-core coil; d_{w} is a center distance of a wire of the air-core coil, d_{w}=d+dₓ−d₀; l is a slot width of the single-segment air-core coil; a calculation formula of the damping coefficient is

$$ζ = \frac{RrC + L}{2 \sqrt{LCR ( R + r )}} ,$$

in which ρ is specific resistance of a wire core; and a calculation formula of the matching resistance in a critical damped state is

$$R = \frac{L}{2 \sqrt{LC} - rC} .$$

In step e, a calculation formula of the resonant angular frequency is

$${ω}_{p} = \sqrt{\frac{1}{LC} ( \frac{r}{R} + 1 )} ,$$

and a calculation formula of the bandwidth is

$${B}_{w} = \frac{1}{2 π \sqrt{LC}} \sqrt{1 + \frac{r}{R}} \sqrt{1 - 2 {ζ}^{2} + \sqrt{4 {ζ}^{4} - 4 {ζ}^{2} + 2}} .$$

The technological and structure parameters of the air-core coil are acquired by solving the parameter qualified equation set of the air-core coil sensor by means of a numerical method.

In step j, the numerical method designed for the technological and structure parameters of the air-core coil sensor includes the following steps:

step 1: calculating and drawing corresponding function curves respectively according to the computational formulas, the value ranges and the qualifications described in steps d-h of FIG. 5; and

step 2: calculating a solution corresponding to the equation set in step i, i.e., the technological and structure parameters of the air-core coil, by using particularities of a projection, an isoline, an extreme point, an intersection point and a tangent point of each curve drawn in step 1.

A method for simulating and designing structure parameters of an air-core coil is provided according to a specific embodiment of the present invention. The method includes the following steps.

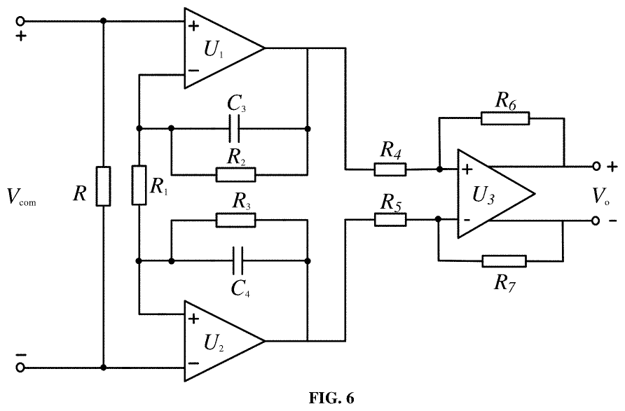

In step a, a pre-amplifying circuit of an air-core coil sensor is designed as shown in FIG. 6, an amplifier is LT1028, and the gain is set to 100 times. According to a circuit model, a transfer function H_{A}(ω) of the pre-amplifying circuit is calculated.

A matching resistor R, amplification factor adjusting resistors R1-R7, filter capacitors C3 and C4, LT028 U1 and U2, and LTC6363 U3 are shown.

In step b, inherent qualifications and value ranges of structure and technological parameters of the air-core coil sensor are identified. The coil is made of nylon into a single-slot skeleton with a slot width of 20 mm and a relative dielectric constant of 2. An enameled wire with a diameter of 0.2 mm, 0.6 mm or 0.8 mm may be used for winding, and enameled leather has a thickness of 0.014 mm, 0.027 mm and 0.03 mm respectively, and a relative dielectric constant of 3.4. The air-core coil has an internal diameter ranging from 0.1 m to 2 m, and a total number of turns ranging from 50 to 200. The air-core coil is parallelly close-wound, and no other spacing materials is inserted between wires.

In step c, equivalent internal resistance r, equivalent inductance L and stray capacitance C of the coil are calculated according to the values and the value ranges of the technological and structure parameters of the coil, a damping coefficient is provided as 1, and the matching resistance R is calculated.

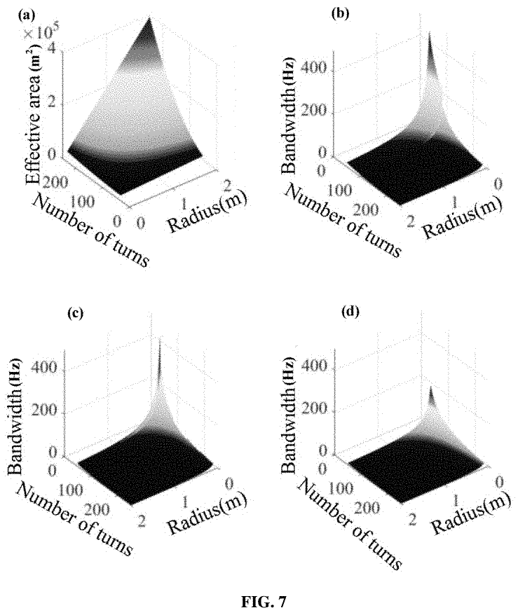

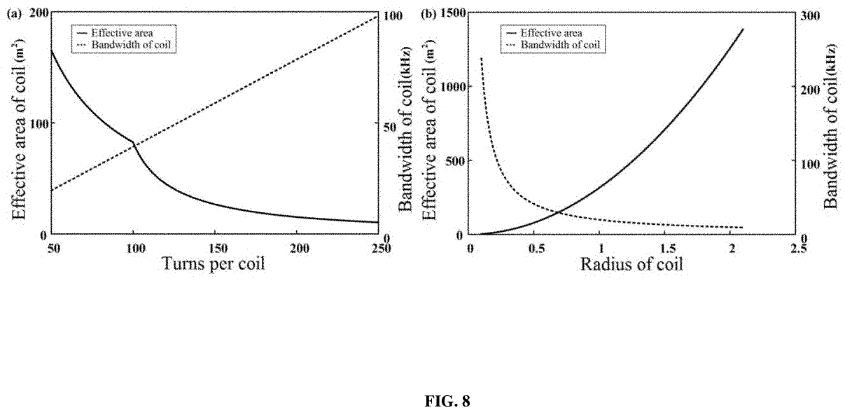

In step d, a transfer function and an equivalent magnetic field sensitivity function of the air-core coil are calculated. This design is aimed for a transient electromagnetic exploration coil, so the effective area of the coil is used to express the equivalent sensitivity of the air-core coil sensor, and the calculation results are shown in FIG. 7(a), in which

(a) indicates the effective area; (b) indicates a bandwidth when the wire diameter is 0.2 mm; (c) indicates a bandwidth when the wire diameter is 0.6 mm; and (d) indicates a bandwidth when the wire diameter is 0.8 mm.

In step e, a resonant angular frequency ω_{c} of the air-core coil is calculated according to the transfer function in step c, then, its equivalent bandwidth B_{w} is calculated, and the calculation results are shown in FIG. 7(b-d).

In step f, an equivalent input magnetic field noise power spectral density Bₙ of the air-core coil sensor is acquired by calculating the equivalent internal resistance thermal noise corresponding to all resistors in the air-core coil sensor, and the equivalent voltage noise and the equivalent current noise at the input terminals of all amplifiers.

In step h, function qualified relations Fₘ and Fᵥ between the mass M and volume V qualifications of the air-core coil and the technological and structure parameters of the air-core coil sensor are identified, and neither the mass nor the volume of the coil is limited in this design.

In step i, a qualified equation set of the technological and structure parameters of the air-core coil is built according to the design requirements on the sensitivity, bandwidth and noise of the air-core coil sensor.

In step j, a design combination of the technological and structure parameters of the air-core coil is acquired by solving a solution of the qualified equation set of the technological and structure parameters of the air-core coil by means of a numerical method.

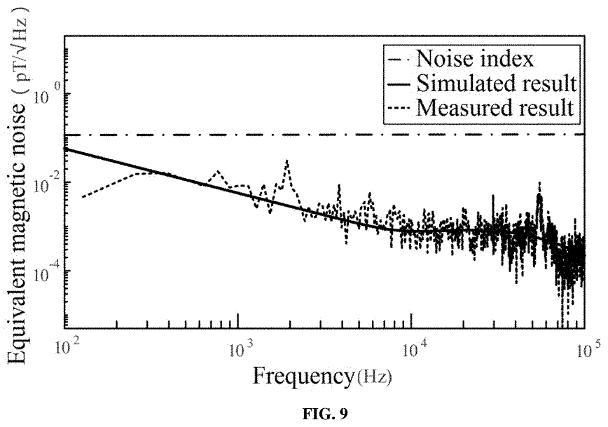

The larger the wire diameter of the air-core coil is, the smaller the equivalent bandwidth of the coil is. In order to ensure the bandwidth of the coil, a 0.2 mm wire is selected. The effective area and bandwidth curves corresponding to different diameters and turns of the air-core coil wound by the 0.2 mm wire are shown in FIG. 8, in which

(a) indicates an optimal design curve of the turns per coil, and (b) indicates a design curve of the diameter of the coil.

In this design, the technological and structure parameters of the air-core coil sensor are solved by using the intersection point of the curve in FIG. 5. By design, the diameter of the coil may be 1.2 m and the turns per coil is 100. The comparison between simulated results and measured results of the equivalent input magnetic field noise of the corresponding coil is shown in FIG. 9.

The present invention aims to protect a method for simulating and designing structure parameters of an air-core coil. The method includes: building an impedance function of an air-core coil according to structure parameters, the air-core coil being of a differential structure and being wound in a completely parallel winding fashion; building a target function of the air-core coil by calculating an equivalent bandwidth, sensitivity and an equivalent noise power spectrum by means of the impedance function; building a qualified function with reference to the target function and structure parameters limit by using a mass and/or volume limit; and acquiring the structure parameters of the air-core coil by calculating an optimal solution of the qualified function. The method is intuitive, and makes calculation of the optimized technological and structure parameters easier and more convenient, thus reducing the amount of calculation and shortening the calculation time.

It should be understood that the foregoing specific embodiments merely serve to exemplarily illustrate or explain the principles of the present invention, and do not constitute a limitation to the present invention. Therefore, any modifications, equivalent substitutions, improvements, etc. made without departing from the spirit and the scope of the present invention should be included in the protection scope of the present invention. In addition, the appended claims of the present invention are intended to cover all changes and modifications that fall within the scope and boundary of the appended claims, or equivalent forms of such scope and boundary.

1. A method for simulating and designing structure parameters of an air-core coil, comprising:
building an impedance function of an air-core coil according to structure parameters, the air-core coil being of a differential structure and being wound in a completely parallel winding fashion;
building a target function of the air-core coil by calculating an equivalent bandwidth, sensitivity and an equivalent noise power spectrum by means of the impedance function;
building a qualified function with reference to the target function and structure parameters limit by using a mass and/or volume limit; and
acquiring structure parameters of the air-core coil by calculating an optimal solution of the qualified function.

2. The method according to claim 1, wherein said building the impedance function of the air-core coil according to the structure parameters comprise:
calculating an internal impedance function of the air-core coil, the internal impedance function comprising an equivalent inductance function, a stray capacitance function and an equivalent internal resistance function;
setting a damping coefficient and calculating a matching resistance function of the air-core coil, wherein
the equivalent inductance function is
$$L = \frac{{μ}_{0} {DN}^{2}}{8} [ ln ( \frac{8 {DN}_{s}}{l} ) - 0.5 ] ;$$
in which, D is an average diameter of the air-core coil, D=(D₀+(d_{c}+d)N_{c}); D₀ is an internal diameter of a skeleton of the air-core coil; d is an external diameter of a coil wire; d_{c} is an inter-layer spacing between coil wires; and N_{c} is the number of wire layers of the air-core coil;
the stray capacitance function is
C=Cₗ+Cₐ+C_{g};
in which,
$${C}_{l} = \frac{{ɛ}_{0} {ɛ}_{l} \sqrt{1 + {( π D \text{/} {d}_{w} )}^{2}}}{36 In ( {d}_{w} \text{/} d )}$$
is an inter-turn capacitance function;
$${C}_{a} = \frac{{ɛ}_{0} {ɛ}_{a} Dl ( {N}_{c} - 1 )}{{N}_{s} {d}_{w} {N}_{c}^{2}}$$
is an inter-layer capacitance function;
$${C}_{g} = \frac{4 {ɛ}_{0} {ɛ}_{g} D ( {d}_{c} + N ) {N}_{c} ( {N}_{s} - 1 )}{3 {eN}_{s}^{2}}$$
is an inter-segment capacitance function, wherein ε₀, εₗ, εₐ and ε_{g} are a dielectric constant of vacuum, a dielectric constant of an inter-turn medium, a dielectric constant of an inter-layer medium and a dielectric constant of an inter-segment medium, respectively; Nₛ is the number of segments of the air-core coil; e is an inter-segment spacing of the air-core coil; d_{w} is a center distance of a wire of the air-core coil; and l is a slot width of the single-segment air-core coil;
the equivalent internal resistance function is
$$r = \frac{4 ρ ( {D}_{0} + ( {d}_{c} + d ) {N}_{c} )}{{d}^{2}} ;$$
in which, ρ is specific resistance of a wire core;
the damping coefficient and the internal impedance function as well as the matching resistance function of the air-core coil meet the following matching function;
$$ζ = \frac{RrC + L}{2 \sqrt{LCR ( R + r )}} ;$$
the damping coefficient can be set to a specific value greater than 1, equal to 1 or less than 1; the air-core coil is in an over-damped state when the damping coefficient is greater than 1; the air-core coil is in a critical damped state when the damping coefficient is equal to 1; and the air-core coil is in an under-damped state when the damping coefficient is less than 1; and
calculating the matching resistance function based on the internal impedance function and the set value of the damping coefficient:
$$R = \frac{( 4 {ζ}^{2} - 2 ) LCr - \sqrt{{[ ( 4 {ζ}^{2} - 2 ) LCr ]}^{2} - 4 ( {r}^{2} {C}^{2} - 4 ζ LC ) {L}^{2}}}{2 ( {r}^{2} {C}^{2} - 4 ζ LC )} .$$

3. The method according to claim 1, wherein said building the target function of the air-core coil by calculating the equivalent bandwidth, the sensitivity and the equivalent noise power spectrum by means of the impedance function specifically comprises:
building an equivalent bandwidth relation function, a sensitivity relation function and an equivalent noise power spectral density relation function by calculating the equivalent bandwidth, the sensitivity and the equivalent noise power spectrum of the air-core coil by means of the impedance function.

4. The method according to claim 3, wherein the equivalent bandwidth function is
$${B}_{w} = \frac{1}{2 π \sqrt{L C}} \sqrt{1 + \frac{r}{R}} \sqrt{1 - 2 {ζ}^{2} + \sqrt{4 {ζ}^{4} - 4 {ζ}^{2} + 2}} ;$$
in which, B_{w} is an equivalent bandwidth function; L is an equivalent inductance function; C is a stray capacitance function; r is an equivalent internal resistance function; ζ is a damping coefficient; and R is a matching resistance function.

5. The method according to claim 3, wherein the sensitivity function is
S_{c}(ω)=2ƒNS|H(ω)|;
in which, H(ω) is a transfer function of an air-core coil sensor, which is acquired by the product of a transfer function H_{c}(ω) of the single-segment air-core coil and a transfer function H_{A}(ω) of a pre-amplifier, i.e., H(ω)=2H_{c}(ω)H_{A}(ω);
the transfer function of the single-segment air-core coil is
$${H}_{c} ( ω ) = \frac{1}{L C \sqrt{{ω}_{p}^{4} + 8 {π}^{2} {f}^{2} ( 2 {π}^{2} {f}^{2} + {ω}_{p}^{2} ( 2 {ζ}^{2} - 1 )}} ;$$
in which,
$${ω}_{p} = \sqrt{\frac{1}{L C} ( \frac{r}{R} + 1 )}$$
is a resonant angular frequency function of the single-segment air-core coil; L is an equivalent inductance function; C is a stray capacitance function; r is an equivalent internal resistance function; ζ is a damping coefficient; and R is a matching resistance function; and
H_{A}(ω) is acquired according to an equivalent circuit model of an actual pre-amplifier.

6. The method according to claim 3, wherein the equivalent noise power spectral density function is
$${B}_{n} ( ω ) = \frac{{E}_{n} ( ω )}{{S}_{c} ( ω )} ;$$
in which, S_{c}(ω) is a sensitivity function of the air-core coil; and
Eₙ(ω)=\sqrt{Eₙᵣ²+Eₙᵢ²+Eₙᵥ²} is an equivalent input voltage noise power spectral density function of the air-core coil sensor; and
in the equivalent input voltage noise power spectral density function, Eₙᵣ, Eₙᵢ and Eₙᵥ are equivalent input resistance thermal noise, equivalent input offset voltage noise and equivalent input offset current noise of the air-core coil sensor, which are acquired by calculating based on the impedance function of the air-core coil and the equivalent circuit model of the actual pre-amplifier.

7. The method according to claim 1, wherein said acquiring the structure parameters of the air-core coil by calculating the optimal solution of the qualified function specifically comprises:
Acquiring the structure parameters by calculating the optimal solution of the qualified function via a numerical method.

8. The method according to claim 1, wherein said acquiring the structure parameters of the air-core coil by calculating the optimal solution of the qualified function comprises:
calculating and drawing a corresponding qualified function curve based on a value range of the structure parameters, the target function and a mass and/or volume limit; and
calculating a solution corresponding to the target function by using particularities of a projection, an isoline, an extreme point, an intersection point and a tangent point of the qualified function curve so as to acquire the structure parameters of the air-core coil.

9. An apparatus for simulating and designing structure parameters of an air-core coil, comprising:
an impedance function building module configured to build an impedance function of the air-core coil according to structure parameters, the air-core coil being of a differential structure and being wound in a completely parallel winding fashion;
a target function building module configured to build a target function of the air-core coil by calculating an equivalent bandwidth, sensitivity and an equivalent noise power spectrum by means of the impedance function;
a qualified function building module configured to build a qualified function with reference to the target function and structure parameters limit by using a mass and/or volume limit; and
a structure parameter calculating module configured to acquire the structure parameters of the air-core coil by calculating an optimal solution of the qualified function.

10. An apparatus according to claim 9, wherein the impedance function building module comprises:
an internal impedance calculating unit configured to calculate an equivalent inductance function, a stray capacitance function and an equivalent internal resistance function of the air-core coil; and
a matching impedance calculating unit configured to set a damping coefficient and to calculate a matching resistance function of the air-core coil, wherein
the equivalent inductance function is
$$L = \frac{{μ}_{0} D {N}^{2}}{8} [ ln ( \frac{8 D {N}_{s}}{l} ) - 0 .5 ] ;$$
in which, D is an average diameter of the air-core coil, and D=(D₀+(d_{c}+d)N_{c});
the stray capacitance function is
C=Cₗ+Cₐ+C_{g};
in which,
$${C}_{l} = \frac{{ɛ}_{0} {ɛ}_{l} \sqrt{1 + {( π D / {d}_{w} )}^{2}}}{36 I n ( {d}_{w} / d )}$$
is an inter-turn capacitance function;
$${C}_{a} = \frac{{ɛ}_{0} {ɛ}_{a} D l ( {N}_{c} - 1 )}{{N}_{s} {d}_{w} {N}_{c}^{2}}$$
is an inter-layer capacitance function; and
$${C}_{g} = \frac{4 {E}_{0} {E}_{g} D ( {d}_{c} + d ) {N}_{c} ( {N}_{s} - 1 )}{3 e {N}_{s}^{2}}$$
is an inter-segment capacitance function;
the equivalent internal resistance function is
$$r = \frac{4 ρ ( {D}_{0} + ( {d}_{c} + d ) {N}_{c} )}{{d}^{2}} ;$$
the damping coefficient and the equivalent inductance function, the stray capacitance function, the equivalent internal resistance function and the matching resistance function of the air-core coil meet the following matching function;
$$ζ = \frac{R r C + L}{2 \sqrt{L C R ( R + r )}} ;$$
the damping coefficient can be set to a specific value greater than 1, equal to 1 or less than 1; the air-core coil is in an over-damped state when the damping coefficient is greater than 1; the air-core coil is in a critical damped state when the damping coefficient is equal to 1; and the air-core coil is in an under-damped state when the damping coefficient is less than 1; and
the matching resistance function is calculated based on the impedance function and the set value of the damping coefficient:
$$R = \frac{( 4 {ζ}^{2} - 2 ) L C r - \sqrt{{[ ( 4 {ζ}^{2} - 2 ) L C r ]}^{2} - 4 ( {r}^{2} {C}^{2} - 4 ζ L C ) {L}^{2}}}{2 ( {r}^{2} {C}^{2} - 4 ζ L C )} .$$

11. The apparatus according to claim 9, wherein the target function building module is specifically configured to build an equivalent bandwidth relation function, a sensitivity relation function and an equivalent noise power spectral density relation function by calculating an equivalent bandwidth, sensitivity and an equivalent noise power spectrum by means of the impedance function.

12. The apparatus according to claim 11, wherein the equivalent bandwidth function is
$${B}_{w} = \frac{1}{2 π \sqrt{L C}} \sqrt{1 + \frac{r}{R}} \sqrt{1 - 2 {ζ}^{2} + \sqrt{4 {ζ}^{4} - 4 {ζ}^{2} + 2}} ;$$
in which, B_{w} is an equivalent bandwidth function; L is an equivalent inductance function; C is a stray capacitance function; r is an equivalent internal resistance function; ζ is a damping coefficient; and R is a matching resistance function.

13. The apparatus according to claim 11, wherein the sensitivity function is
S_{c}(ω)=2πfNS|H(ω)|;
in which, H(ω) is a transfer function of an air-core coil sensor, which is acquired by the product of a transfer function H_{c}(ω) of the single-segment air-core coil and a transfer function H_{A}(ω) of a pre-amplifier, i.e., H(ω)=2H_{c}(ω)·H_{A}(ω);
the transfer function of the single-segment air-core coil is
$${H}_{c} ( ω ) = \frac{1}{L C \sqrt{{ω}_{p}^{4} + 8 {π}^{2} {f}^{2} ( 2 {π}^{2} {f}^{2} + {ω}_{p}^{2} ( 2 {ζ}^{2} - 1 )}} ;$$
in which,
$${ω}_{p} = \sqrt{\frac{1}{L C} ( \frac{r}{R} + 1 )}$$
is a resonant angular frequency function of the single-segment air-core coil; L is an equivalent inductance function; C is a stray capacitance function; r is an equivalent internal resistance function; Cis a damping coefficient; and R is a matching resistance function; and
H_{A}(ω) is acquired according to an equivalent circuit model of an actual pre-amplifier.

14. The apparatus according to claim 11, wherein the equivalent noise power spectral density function is
$${B}_{n} ( ω ) = \frac{{E}_{n} ( ω )}{{S}_{c} ( ω )} ;$$
in which, S_{c}(ω) is a sensitivity function of the air-core coil and Eₙ(ω)=\sqrt{Eₙᵣ²+Eₙᵢ²+Eₙᵥ²} is an equivalent input voltage noise power spectral density function of the air-core coil sensor; and
in the equivalent input voltage noise power spectral density function, Eₙᵣ, Eₙᵢ and Eₙᵥ are equivalent input resistance thermal noise, equivalent input offset voltage noise and equivalent input offset current noise of the air-core coil sensor respectively, which are acquired by calculating based on the impedance function of the air-core coil and the equivalent circuit model of the actual pre-amplifier.

15. The apparatus according to claim 9, wherein the structure parameter calculating module is specifically configured to acquire the structure parameters by calculating an optimal solution of the qualified function via a numerical method.

16. The apparatus according to claim 9, wherein the structure parameter calculating module comprises:
a qualified function curve drawing module configured to calculate and draw a corresponding qualified function curve based on a value range of the structure parameters, the target function and a mass and/or volume limit; and
a structure parameter calculating module configured to calculate a solution corresponding to the target function by using particularities of a projection, an isoline, an extreme point, an intersection point and a tangent point of the qualified function curve so as to acquire the structure parameters of the air-core coil.

17-18. (canceled)
